(19) United States
(12) Patent Application Publication
(10) Pub. No.: US 2024/0120923 A1
(43) Pub. Date: Apr. 11, 2024

(54) SPIN LOGIC DEVICE BASED ON MAGNETIC TUNNEL JUNCTION AND ELECTRONIC APPARATUS COMPRISING THE SAME

(71) Applicant: Institute of Physics, Chinese Academy of Sciences, Beijing City (CN)

(72) Inventors: Xiufeng HAN, Beijing City (CN); Caihua WAN, Beijing City (CN); Mingkun ZHAO, Beijing City (CN); Ran ZHANG, Beijing City (CN)

(21) Appl. No.: 18/482,141

(22) Filed: Oct. 6, 2023

(30) Foreign Application Priority Data
Oct. 8, 2022 (CN) 202211221977.7

(51) Int. Cl. H03K 19/18; G06F 7/46; G11C 11/16; H01F 10/32; H03K 19/21

(52) U.S. Cl. CPC H03K 19/18; G06F 7/461; G11C 11/161; G11C 11/1675; H01F 10/3254; H03K 19/21

(57) ABSTRACT

Provided are a spin logic device based on a magnetic tunnel junction and an electronic apparatus comprising the same. According to an embodiment, the spin logic device may comprise: a current wiring; a magnetic tunnel junction, which comprises a free magnetic layer, a fixed magnetic layer, and a potential barrier layer located therebetween, which are stacked on the current wiring; and a current source for providing an input current to the current wiring, wherein the input current comprises a first, a second, and a third in-plane currents, directions of which are different from a direction of a magnetization axis of the free magnetic layer or there is a vertical component in that direction, and the first and the second in-plane currents are logical input currents while the third in-plane current is used to control the implementation mode of the spin logic device.

### CROSS-REFERENCE

The present disclosure claims a benefit of, and priority to Chinese Patent Application No. 202211221977.7 filed on Oct. 8, 2022, the disclosure of which is hereby expressly incorporated by reference herein in its entirety.

### TECHNICAL FIELD OF THE DISCLOSURE

This application generally belongs to the technical field of spin electronics, and more specifically, relates to a spin logic device based on a magnetic tunnel junction, which can operate under a zero magnetic field, and further relates to an electronic apparatus comprising the spin logic device.

### BACKGROUND

Boolean logic devices and adders are the core of computer computing units, which are generally implemented through CMOS circuits. Due to issues such as energy consumption and atomic scale, traditional logic devices are no longer able to meet the exponentially increasing demand for computing capability development. Comparing to traditional semiconductor devices, reconfigurable logic devices based on electron spin dependent transport characteristics have advantages such as high operating frequency, infinite number of reconfigurations, low read and write power consumption, and nonvolatility of logic information.

Magnetic tunnel junctions (MTJs) are the core units of spin logic devices. There have been reports of implementing adders based on spin transfer torque (STT) type logic devices, which are based on one or more spin transfer torque magnetic tunnel junctions (STT-MTJs) and complemented by CMOS servo circuits to achieve corresponding operational functions. Comparing to STT-MTJ, spin orbit torque magnetic tunnel junctions (SOT-MTJ) have advantages in performance such as cyclic erasure lifetime, write speed, and write energy consumption. Therefore, developing spin logic and operational devices based on the SOT effect is another effective way to achieve multifunctional nonvolatile programmable logic and operational devices through spin electronics schemes.

However, logic devices based solely on the SOT effect or spin Hall effect require an additional external magnetic field to assist in magnetic moment flipping. For practical devices, the external magnetic field is not a convenient external condition for manipulation. Since it has non locality and may cause circuit interference, and moreover, the generation of variable polarity magnetic fields rely on large currents and wires, which is not conducive to reducing the power consumption of the device and miniaturizing the device. Therefore, developing SOT spin logic devices under a zero magnetic field is the key to exploring practical spin logic devices.

This type of SOT type spin logic device under a zero magnetic field can be divided into two categories: schemes with completely or partially perpendicular magnetic anisotropy magnetic layers and schemes with only in-plane magnetic anisotropy magnetic layers, which can adjust the magnetic moment flipping characteristics of SOT drive by utilizing an in-plane magnetic moment or an external bias voltage, and use it as a control method to achieve programmable logic and operations. However, the tunnel junction design of such schemes is still relatively complex; for example, it needs to design a free layer with a “T” type magnetic structure and a magnetic tunnel junction with voltage controlled magnetic anisotropy (VCMA).

### SUMMARY

In view of this, an objective of the present disclosure is to provide a spin logic device having a simple magnetic tunnel junction structure. The present disclosure can conveniently and quickly construct spin logic devices based on MTJ to reduce device complexity and development risks of MTJ technology.

Some embodiments of the present disclosure provide a spin logic device based on a magnetic tunnel junction, comprising: a current wiring; a magnetic tunnel junction having a free magnetic layer, a fixed magnetic layer, and a potential barrier layer located therebetween, which are stacked on the current wiring; and a current source for providing an input current to the current wiring, wherein the input current comprises a first, a second, and a third in-plane current, and directions of the first, second, and third in-plane currents are perpendicular to the direction of the magnetization axis of the free magnetic layer or there is a vertical component in that direction. At least one of the first in-plane current and the second in-plane current is configured as a logical input current of the spin logic device, and the third in-plane current is used to control the implementation mode of the spin logic device.

In some examples, the spin logic device further comprises a current-direction control element for controlling the input direction of the input current.

In some examples, the current-direction control element comprises a gating switch.

In some examples, the spin logic device is configured to be implemented as a logical AND gate, a logical OR gate, a logical NOT gate, a logical NAND gate, or a logical XOR gate by setting the magnitude and direction of the first in-plane current, the second in-plane current, and the third in-plane current.

In some examples, the first in-plane current, the second in-plane current, and the third in-plane current are pulse currents.

Some embodiments of the present disclosure provide a spin logic device based on a magnetic tunnel junction, comprising: a current wiring; a magnetic tunnel junction having a free magnetic layer, a fixed magnetic layer, and a potential barrier layer located therebetween, which are stacked on the current wiring; a current source for providing an input current to the current wiring, wherein a direction of the input current is perpendicular to a direction of a magnetization axis of the free magnetic layer or there is a vertical component in that direction; and a current-direction switching element for switching the input direction of the input current under a control signal, wherein the input current and the control signal are configured as logical inputs to the spin logic device.

In some examples, the current-direction switching element comprises two pairs of gating switches, each pair of which is connected to both sides of the current wiring, and the control signals of the two pairs of gating switches are reversed.

In some examples, the spin logic device is configured to be implemented as a logic XOR gate or logic XNOR gate by setting a magnitude of the input current and the control signal.

Some embodiments of the present disclosure provide an adder that comprises one or more combinations of the spin logic devices mentioned above.

Some embodiments of the present disclosure further provide an electronic apparatus that comprises an adder as described above. The electronic apparatus is, for example, one of a computer, a mobile phone, a media player, a personal digital assistant, and a wearable electronic apparatus.

In the present disclosure, a spin logic device with a simple in-plane magnetic tunnel junction structure is proposed, which can operate in different modes through the regulation of current direction and magnitude, achieving a wide variety of spin logic devices and reduce device complexity.

### BRIEF DESCRIPTION OF THE DRAWINGS

In order to provide a clearer explanation of the technical solutions and advantages of the specific implementations of the present disclosure, the accompanying drawings used will be briefly explained below.

FIG. 1 is a schematic diagram of the structure of a spin logic device according to an embodiment of the present disclosure;

FIG. 2 is a schematic diagram of the structure of a spin logic device in an exemplary embodiment of the present disclosure;

FIG. 3 is a circuit schematic diagram of a spin logic device according to an embodiment of the present disclosure;

FIGS. 4A and 4B show the R-I curves of the magnetic tunnel junction in different circuits according to an embodiment of the present disclosure;

FIG. 5 is a circuit schematic diagram of a spin logic device according to an embodiment of the present disclosure.

### DETAILED DESCRIPTION

Below, exemplary embodiments of the present disclosure will be described in detail with reference to the accompanying drawings. Obviously, the described embodiments are only a part of the embodiments of this disclosure, not all of them. It should be understood that this disclosure is not limited by the example embodiments described here. Unless otherwise limited, the technical terms used in this article have the meanings commonly understood by those skilled in the art.

One objective of the present disclosure is to provide a spin logic device based on a magnetic tunnel junction with a simple structure. FIG. 1 shows a schematic diagram of the structure of a spin logic device according to an embodiment of the present disclosure. As shown in FIG. 1, a spin logic device 100 comprises a current wiring 110, a magnetic tunnel junction 120 located on the current wiring 110, and a current source 130 connected to the current wiring 110. The magnetic tunnel junction 120 at least comprises a free magnetic layer 122, a fixed magnetic layer 126, and a potential barrier layer 124 located therebetween, which are stacked on the current wiring 110.

The current wiring 110 may be electrically connected to the magnetic tunnel junction 120. The current wiring 110 may be made of non-magnetic metals, and its interaction with the interface between the free magnetic layer 122 and it is a SOT effect. For example, the magnetic tunnel junction 120 is in contact with the current wiring 110, and when a current value of the current passing through the current wiring reaches a preset range, it can stimulate the free magnetic layer 122 to flip the magnetization direction without arranging an external magnetic field. On both sides of the current wiring 110, there can be arranged with ports for passing currents to form a logic circuit with external current sources and other devices.

The magnetic tunnel junction 120 is a sandwich structure composed of the free magnetic layer 122, the tunneling barrier layer 124, and the fixed magnetic layer 126. For the spin orbit torque type magnetic tunnel junction, a magnetization direction of the fixed magnetic layer 126 can be fixed to a certain direction through artificial antiferromagnetic pinning. A magnetization direction of the free magnetic layer 122 can be flipped by an external magnetic field or current drive, where the external magnetic field direction is along a direction of the magnetization axis of the free layer. An external current enters along the current wiring 110 located below the free magnetic layer 122. As shown in FIG. 1, the external current I parallel to the film surface can enter the current wiring 110, the direction of which is perpendicular to the direction of the magnetization axis of the free magnetic layer or has a vertical component in that direction. That is, the current density direction of the external current I can have a non 0° angle with the magnetization axis direction of the free magnetic layer, and the two are not completely parallel. Therefore, the SOT effect can be generated in the free magnetic layer 122 to change the magnetization direction of the free magnetic layer 122.

The current source 130 is used to provide an input current (i.e. external current I) to the current wiring 110. In order to achieve a Boolean logic function, in one embodiment, the input current I can comprise a first current IA, a second current IB, and a third current IC, and the directions of the three currents are perpendicular to the magnetization axis direction of the free magnetic layer 122. The first current IA and the second current IB can be the logic input current, and the third current IC can be a control current used to control the implementation mode of the spin logic device. The combined action of the three currents can flip the magnetization direction of the free magnetic layer 122, and the specific operation thereof will be described in detail below. It should be noted that although the direction of the input current I shown in the diagram is input from one side of the current wiring 110, in some embodiments, the direction of the input current I can be switched, namely to be switched to input from the other side of the current wiring 110. The directions of the input currents determine the spin polarization direction of the contact surface between the current wiring and the free magnetic layer 122. By switching the direction of the input current, the resistance-current dependence curve of the magnetic tunnel junction 120 can also be flipped, which facilitates the implementation of a spin logic device with a wide variety of functions and its specific operation will also be described in detail below.

By an embodiment of the present disclosure, a spin logic scheme with a simple in-plane magnetic tunnel junction structure is provided, which utilizes two characteristics of SOT-MTJ: (1) the write channel resistance of SOT-MTJ is insensitively dependent on the magnetic structure of the magnetic tunnel junction, and (2) the spin current polarization direction generated by the spin Hall effect of non magnetic metals only depends on the current direction. Therefore, by reversing the current direction, the flipping direction (clockwise or counterclockwise) of the resistance-current dependence curve of the magnetic tunnel junction can also be reversed. By taking use of this feature, the present disclosure can achieve a functionally rich spin logic device by controlling the magnitude and input direction of the input current. Below, some specific examples will be provided to illustrate the design of spin logic devices.

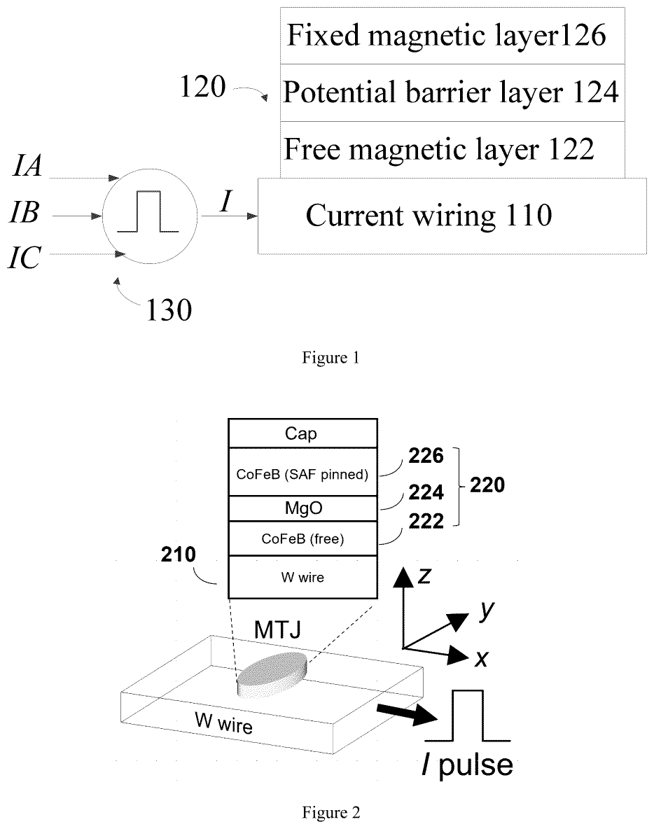

FIG. 2 shows a schematic diagram of the structure of a spin logic device in an exemplary embodiment of the present disclosure. As shown in FIG. 2, the spin logic device 200 may comprise a current wiring 210 and a magnetic tunnel junction 220 stacked on it. The current wiring 210 can be made of non-magnetic metals such as W, Ta, Pt, or other spin current source materials with strong spin orbit coupling. The magnetic tunnel junction 220 can at least comprise a free magnetic layer 222 in direct contact with the current wiring 210, a barrier layer 224 and a fixed magnetic layer 226 which are stacked on it. Both the free magnetic layer 222 and the fixed magnetic layer 226 exhibit in-plane uniaxial magnetic anisotropy, meaning that their magnetization axes are parallel to the plane, i.e. along the Y-axis direction in FIG. 2. Both the free magnetic layer 212 and the reference magnetic layer 216 can be formed from ferromagnetic materials. Although FIG. 2 shows that the free magnetic layer 222 and the fixed magnetic layer 226 are CoFeB, other materials such as Co, Fe, Ni, and alloys comprising Co, Fe, Ni, such as CoFe, NiFe, etc. can also be used. In some embodiments, the magnetic moment of the fixed magnetic layer 226 can be fixed by such as a pinning structure or a self-pinning structure. In the pinning structure, a pinning layer (not shown) can be formed on the fixed magnetic layer 226 to fix the magnetic moment of the magnetic layer 226. The pinning layer is generally formed by antiferromagnetic materials such as IrMn. Alternatively, the fixed magnetic layer 226 can be formed from a hard magnetic material with high coercivity, or a larger coercivity can be obtained by adjusting the thickness of the fixed magnetic layer 226, in which case the pinning layer can be omitted. In some embodiments, an anti-oxidation protective layer, which is generally formed by metal materials such as Ta with good conductivity and chemical stability, may also be provided above the fixed magnetic layer 226.

Referring to FIG. 2, the input current from the current source flows in from one side of the current wiring 210, and the current direction may be perpendicular to the direction of the magnetization axis of the free magnetic layer 222 or in a state of non-zero angle with the magnetization axis. Through the SOT effect between the current wiring 210 and the free magnetic layer 222 of the magnetic tunnel junction, the spin polarized electron flow may promote the reversal of the magnetization direction of the free magnetic layer 222, namely the transition of magnetic tunnel junctions between high and low resistance states, which can be determined by applying a current flowing through the magnetic tunnel junction in a perpendicular direction, can be achieved by changing the current magnitude.

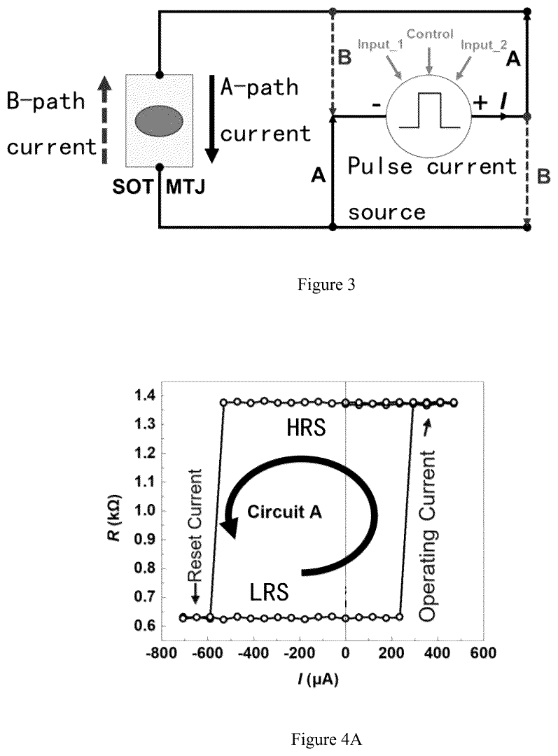

FIG. 3 is a circuit schematic diagram of a spin logic device according to an embodiment of the present disclosure. As shown in FIG. 3, a pulse current source may be used as the current source, and it consists of three input currents, wherein the first and second current Input_1 and Input_2 may be used as the first logic input current and the second logic input current (i.e. corresponding to IA, IB in FIG. 1), and the third current Control is used to control the implementation mode of the spin logic device (i.e. corresponding to IC in FIG. 1). Namely, by controlling the magnitude and direction of the first, second, and third currents, the spin logic device can operate as different Boolean logic operations such as a logic AND gate, an OR gate, a NOT gate, a NAND gate, or a XOR gate.

Three circuit current Input_1, Input_2 and Control may be implemented as a circuit with a certain magnitude and direction. If the directions of the three currents are in parallel, the current I output by the pulse current source can be expressed as I=Input_1+Input_2+Control. The logic input current Input_1 and Input_2 may be defined that the logic inputs are 1 when the current values of the logic input current Input_1 and Input_2 are a preset value (e.g. 100 μA), respectively, and the logic input are 0 when the current values are 0, respectively. The magnitude of the current Control may control the switching of the spin logic devices between different logic gates. In one example, the low and high resistance states of the magnetic tunnel junction can serve as the logical outputs of the spin logic device. For example, the low resistance state corresponds to a logical output 0, while the high resistance state corresponds to a logical output 1.

In an embodiment, the direction of the input current into the current wiring 210 from the pulse current source has two modes. As shown in FIG. 3, when the input current flows from the first side of the current wiring to the opposite second side, this mode is illustrated as an A-path current; when the input current flows from the second side of the current wiring to the first side, this mode is illustrated as a B-path current. In the two modes, the current flowing through the write channel of the magnetic tunnel junction 220 has opposite directions, and correspondingly, the flipping directions of the resistance-current dependence curve of magnetic tunnel junction 220 are also opposite with each other.

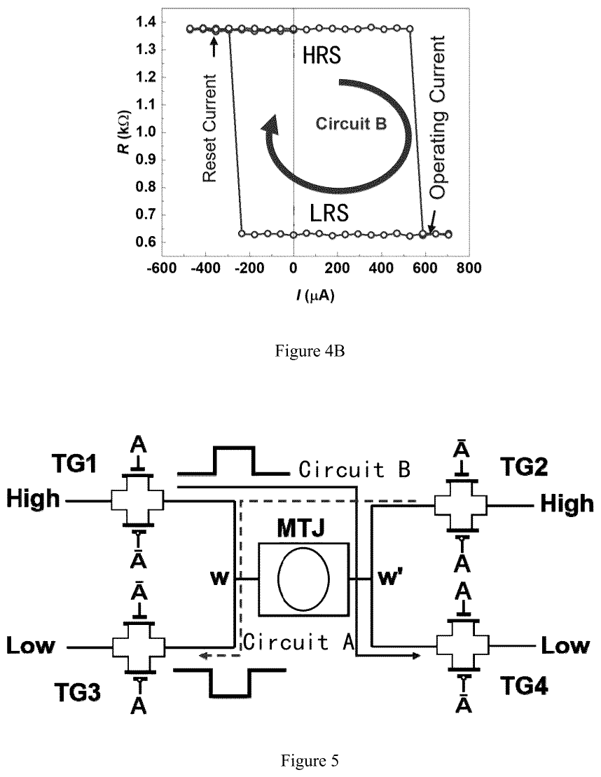

FIGS. 4A and 4B respectively show the resistance-current (R-I) curves of the magnetic tunnel junction in one embodiment of the present disclosure under different circuit modes. As shown in FIG. 4A, in an A-circuit mode, firstly, a current (e.g. −600 μA) is applied to the current wiring to keep the magnetic tunnel junction MTJ in a predetermined initial state (low resistance state (LRS)), and the flipping direction of the R-I curve is counterclockwise, then when the operating current reaches the critical current (250 μA), the magnetic tunnel junction flips into a high resistance state. As shown in FIG. 4B, in the B-circuit mode, firstly, a current (e.g. −300 μA) is applied to the current wiring to keep the magnetic tunnel junction MTJ in a predetermined initial state (high resistance state (HRS)), and the flipping direction of the R-I curve is clockwise, then when the operating current reaches the critical current (530 μA), the magnetic tunnel junction flips into a low resistance state. By utilizing the characteristic that the flipping direction of the resistance-current curve of the magnetic tunnel junction is related to the current direction, a functionally rich spin logic device can be achieved.

In an embodiment, the input direction of the input current can be controlled by setting a current direction controlling device, thereby in turn controlling the flipping direction of the R-I curve of the magnetic tunnel junction. For example, in the circuit shown in FIG. 3, several interconnected gating switches (such as respectively set at solid line A and dashed line B) can be set to switch the logic device from the A-circuit mode to the B-circuit mode. The gating switch may be a MOS transistor, a transmission gate, a transistor, etc. For example, when the gating switch in a circuit A is on, the gating switch in the circuit B is off, and vice versa. FIG. 5 shows a specific circuit implementation, which will be described later. By controlling the on and off of the gating switch, the spin logic device can switch between the A-circuit mode and the B-circuit mode, and correspondingly, the R-I flipping direction of the magnetic tunnel junction will also be reversed.

The operating principle of spin logic device 200 will be explained below with reference to FIGS. 3, 4A, and 4B. In one embodiment, the spin logic device 200 can be set to be in the A-circuit mode, and its R-I curve is as shown in FIG. 4A. The process of logical operation can comprise two steps, namely a circuit reset step and a logic operation step. In the circuit reset step, refer to FIG. 3, first set the currents Input_1, Input_2 and the current Control to 0, 0, and the first reset current (e.g., −600 μA), respectively. Therefore, the input current I=−600 μA. This current can reset the magnetic tunnel junction to a low resistance state, at which point the logic output of the spin logic device is 0.

When the logic device enters the logical operation step, the control circuit Control may maintain the first operating current (e.g., 100 μA). When both of Input_1 and Input are 100μ or when both of them are logical input 1, the input current of the current wiring I=+300 μA, and due to the forward critical current of the magnetic tunnel junction being 250 μA, the tunnel junction can be flipped to a high resistance state, with a corresponding logical output of 1. Otherwise, if one or both of Input_1 and Input_2 are logical inputs 0 (i.e., the corresponding current is 0), the input current I is +200 μA or +100 μA, all of which are below the critical current 250 μA. At this point, the magnetic tunnel junction cannot be flipped to the high resistance state, but can only be maintained in the low resistance state; that is, the logical output is maintained in the 0 state.

It should be noted that when the magnetization direction of the free magnetic layer flips, the state of the magnetic tunnel junction changes and no longer remains in its initial state, which will affect subsequent logical operations. Therefore, before each logic operation, a reset operation can be performed on the spin logic device to ensure consistency in the initial state of the magnetic tunnel junction.

As mentioned above, spin logic device 200 achieves logical AND operations in accordance with the truth table shown in Table 1.

TABLE 1
Operation steps and truth table of the logical AND gate

| | Input_1 | | Input_2 | | | | I | | Output | |
|---|---|---|---|---|---|---|---|---|---|---|
| | Logic | | Logic | | Control | | Input | | Logic | Resistance |
| | input | Current | input | Current | Current | | current | | output | state |
| Reset | Non | 0 | Non | 0 | −600 | μA | −600 | μA | 0 | Low |
| Operation | 0 | 0 | 0 | 0 | 100 | μA | 100 | μA | 0 | Low |
| | 1 | 100 μA | 0 | 0 | 100 | μA | 200 | μA | 0 | Low |
| | 0 | 0 | 1 | 100 μA | 100 | μA | 200 | μA | 0 | Low |
| | 1 | 100 μA | 1 | 100 μA | 100 | μA | 300 | μA | 1 | High |

The spin logic device provided in the embodiments of this application has flexible programmable characteristics. As described earlier, when the control current Control is set to a predetermined value, the spin logic device 200 can be implemented as a logic AND gate. When the magnitude of the control current Control in the logic operation step is changed, the function of the spin logic device can be changed. For example, when the control current Control is adjusted from 100 μA to 200 μA while the definitions of other logic inputs and outputs remain unchanged, the spin logic device can operate as a logic “OR” gate.

Specifically, still referring to FIGS. 3 and 4A, first set the spin logic device 200 in the A-circuit mode and set input_1, Input_2, and the control current Control to 0, 0, and the second reset current (for example, −600 μA), which is equal to the first reset current to improve the operability of the device, so the input current I=−600 μA, which current can reset the magnetic tunnel junction to a low resistance state, at which point the logic output of the spin logic device is 0.

When the logic device enters the logical operation step, the control circuit Control can maintain the second operating current (e.g., 200 μA). When one or both of Input_1 and Input_ are logical input 1 (corresponding current is 100 μA), the input current I of the current wiring is +300 μA or +400 μA. Because the forward critical current of the magnetic tunnel junction is 250 μA, the tunnel junction can be flipped to a high resistance state, with a corresponding logical output of 1. Otherwise, if both of Input_1 and Input_2 are logical inputs 0 (i.e., the corresponding current is 0), then the input current I is +200 μA, below the critical current 250 μA. At this point, the magnetic tunnel junction cannot be flipped to the high resistance state, but can only be maintained in the low resistance state; that is, the logical output is maintained in the 0 state.

It should be noted that when the magnetization direction of the free magnetic layer flips, the state of the magnetic tunnel junction changes and no longer remains in its initial state, which will affect subsequent logical operations. Therefore, before each logic operation, a reset operation can be performed on the spin logic device to ensure consistency in the initial state of the magnetic tunnel junction.

It is understandable that although the control current is 200 μA used as an example to describe the operations of OR gate logic, the implementation manner of this application is not limited to this, and the control current can be selected or adjusted according to different MTJ to achieve logical OR gate operations.

As mentioned above, the spin logic device 200 implements logical OR operations that comply with the truth table shown in Table 2.

TABLE 2
Operation steps and truth table of the logical OR gate

| | Input_1 | | Input_2 | | | | I | | Output | |
|---|---|---|---|---|---|---|---|---|---|---|
| | Logic | | Logic | | Control | | Input | | Logic | Resistance |
| | input | Current | input | Current | Current | | current | | output | state |
| Reset | Non | 0 | Non | 0 | −600 | μA | −600 | μA | 0 | Low |
| Operation | 0 | 0 | 0 | 0 | 200 | μA | 200 | μA | 0 | Low |
| | 1 | 100 μA | 0 | 0 | 200 | μA | 300 | μA | 1 | High |
| | 0 | 0 | 1 | 100 μA | 200 | μA | 300 | μA | 1 | High |
| | 1 | 100 μA | 1 | 100 μA | 200 | μA | 300 | μA | 1 | High |

The above example describes the implementation manner of a spin logic device in the A-circuit mode. If the spin logic device is switched from the A-circuit mode to the B-circuit mode, the R-I flipping characteristic of the tunnel junction will be converted from the curve shown in FIG. 4A to the curve shown in FIG. 4B. The difference between these two flipping characteristics is that their flipping direction switches from counterclockwise to clockwise. In this circuit mode, various Boolean logic functions can also be achieved by adjusting the current Control setting, while following the same definition as the logic input and the logic output mentioned above. By switching the circuit modes, this application can achieve a wide variety of functions for spin logic device through a simple magnetic tunnel junction structure, reduce device complexity, and the current only needs to be slightly tuned to achieve the transformation of different logic functions, reducing device power consumption.

Referring to FIGS. 3 and 4B below, the operation mode of the spin logic devices implemented as “NAND” gate, “NOR” gate, and “NOT” gate will be explained.

In an embodiment, the spin logic device 200 can be set to be in the B-circuit mode through a gating switch or other means, and its R-I curve is shown in FIG. 4B. The process of logical operation can comprise two steps, namely a circuit reset step and a logic operation step. In the reset step, referring to FIG. 3, first, the Input_1, Input_2 and the control current Control are set to 0, 0, and the third reset current (for example, −300 μA), respectively. Therefore, the input current I=−300 μA, and it can reset the magnetic tunnel junction to a high resistance state. At this time, the logic output of the spin logic device is 1.

When the logic device enters the logical operation steps, the control circuit Control can maintain the third operating current (e.g., 400 μA). When both of Input_1 and Input_2 are 100 μA or both are the logical input 1, the input current of the current wiring I=+600 μA. Because the forward critical current of the magnetic tunnel junction is 530 μA, the tunnel junction can be flipped to a low resistance state, and the corresponding logical output is 0. Otherwise, if one or both of Input_1 and Input_2 are the logical inputs 0 (i.e., the corresponding current is 0), the input current I is +400 μA or +500 μA, all of which are below critical current 530 μA. At this point, the magnetic tunnel junction cannot be flipped to the low resistance state and can only be maintained in the high resistance state; that is, the logical output is maintained in the 1 state.

It should be noted that when the magnetization direction of the free magnetic layer flips, the state of the magnetic tunnel junction changes and no longer remains in its initial state, which will affect subsequent logical operations. Therefore, before each logic operation, a reset operation can be performed on the spin logic device to ensure consistency in the initial state of the magnetic tunnel junction.

As mentioned above, the spin logic device 200 implements logical NAND operations in accordance with the truth table shown in Table 3.

TABLE 3
Operation steps and truth table of the logic “NAND” gate.

| | Input_1 | | Input_2 | | | | I | | Output | |
|---|---|---|---|---|---|---|---|---|---|---|
| | Logic | | Logic | | Control | | Input | | Logic | Resistance |
| | input | Current | input | Current | Current | | current | | output | state |
| Reset | Non | 0 | Non | 0 | −300 | μA | −300 | μA | 1 | High |
| Operation | 0 | 0 | 0 | 0 | 400 | μA | 400 | uA | 1 | High |
| | 1 | 100 μA | 0 | 0 | 400 | μA | 500 | μA | 1 | High |
| | 0 | 0 | 1 | 100 μA | 400 | μA | 500 | μA | 1 | High |
| | 1 | 100 μA | 1 | 100 μA | 400 | μA | 600 | μA | 0 | Low |

The spin logic device provided in the embodiments of the present disclosure has flexible programmable characteristics. The previous description described the process of implementing the spin logic device 200 as a logic NAND gate when the control current Control is set to a predetermined value in the B-circuit mode. When the control current Control in the logic operation step is changed, the function of the spin logic device can be changed accordingly. For example, when the control current Control is adjusted from 400 μA to 500 μA while the definitions of other logic inputs and outputs remain unchanged, the spin logic device can operate as a logic “NOR” gate.

Specifically, referring to FIGS. 3 and 4B again, first set the spin logic device 200 in the B-circuit mode and set Input_1, input_2, and the control current Control to 0, 0, and the fourth reset current (for example, −300 μA) which is equal to the third reset current to improve the operability of the device, respectively, so the input current I=−300 μA, and it can reset the magnetic tunnel junction to a high resistance state, where the logic output of the spin logic device is 1.

When the logic device enters the logic operation steps, the control circuit Control can maintain the fourth operating current (e.g., 500 μA). When one or both of the Input_1 and Input_2 are logical input 1 (corresponding current is 100 μA), the input current I of the current wiring is +600 μA or +700 μA. Because the forward critical current of the magnetic tunnel junction at this time is 530 μA, the tunnel junction can be flipped to a low resistance state, and the corresponding logical output is 0. Otherwise, if both of Input_1 and Input_2 are logical inputs 0 (i.e., the corresponding current is 0), the input current I is +500 μA, which is below the critical current 530 μA. At this point, the magnetic tunnel junction cannot be flipped to the low resistance state, but can only be maintained in the high resistance state, i.e., the 1 state.

It should be noted that when the magnetization direction of the free magnetic layer flips, the state of the magnetic tunnel junction changes and no longer remains in its initial state, which will affect subsequent logical operations. Therefore, before each logic operation, a reset operation can be performed on the spin logic device to ensure consistency in the initial state of the magnetic tunnel junction.

As mentioned above, the spin logic device 200 implements logical NOR operations in accordance with the truth table shown in Table 4.

TABLE 4
Operation steps and truth table of the logical XOR gate

| | Input_1 | | Input_2 | | | | I | | Output | |
|---|---|---|---|---|---|---|---|---|---|---|
| | Logic | | Logic | | Control | | Input | | Logic | Resistance |
| | input | Current | input | Current | Current | | current | | output | state |
| Reset | Non | 0 | Non | 0 | −300 | μA | −300 | μA | 1 | High |
| Operation | 0 | 0 | 0 | 0 | 500 | μA | 500 | μA | 1 | High |
| | 1 | 100 μA | 0 | 0 | 500 | μA | 600 | μA | 0 | Low |
| | 0 | 0 | 1 | 100 μA | 500 | μA | 600 | μA | 0 | Low |
| | 1 | 100 μA | 1 | 100 μA | 500 | μA | 700 | μA | 0 | Low |

Due to the fact that the “NOT” gate can serve as a subset of the “NOR” gate or the “NAND” gate, the spin logic device can also be implemented as a “not” gate by disabling one of the input currents. For example, referring to FIGS. 3 and 4B, first set the spin logic device 200 to the B-circuit mode and disable Input_2 (i.e., its current is considered as 0), while setting the Input_1 and the control current Control to 0 and the fifth reset current (e.g., −300 μA) which can be equal to the third and fourth reset currents, respectively, thereby improving the operability of the device. Therefore, the input current I=−300 μA and this current can reset the magnetic tunnel junction to a high resistance state, where the logic output of the spin logic device is 1.

When the logic device enters the logical operation steps, the control circuit Control can maintain the fifth operating current (e.g., 500 μA), which may be equal to the fourth operating current. When Input_1 is the logical input 1 (the corresponding current is 100 μA), the input current I of the current wiring is +600 μA. Because the forward critical current of the magnetic tunnel junction is 530 μA, the tunnel junction can be flipped to a low resistance state, and the corresponding logical output is 0. Otherwise, when Input_1 is the logical input 0 (i.e., the corresponding current is 0), the input current I is +500 μA, which is below the critical current 530 μA. At this point, the magnetic tunnel junction cannot be flipped to the low resistance state, but it can only be maintained in the high resistance state; that is, the logical output is maintained in the 1 state.

It should be noted that when the magnetization direction of the free magnetic layer flips, the state of the magnetic tunnel junction changes and no longer remains in its initial state, which will affect subsequent logical operations. Therefore, before each logic operation, a reset operation can be performed on the spin logic device to ensure consistency in the initial state of the magnetic tunnel junction.

As mentioned above, the spin logic device 200 implements logical OR (NOT) operations that conform to the truth table shown in Table 5.

TABLE 5
Operation steps and truth table of the logical NOR gate

| | Input_1 | | Input_2 | | | | I | | Output | |
|---|---|---|---|---|---|---|---|---|---|---|
| | Logic | | Logic | | Control | | Input | | Logic | Resistance |
| | input | Current | input | Current | Current | | current | | output | state |
| Reset | Non | 0 | Non | 0 | −300 | μA | −300 | μA | 1 | High |
| Operation | 0 | 0 | 0 | 0 | 500 | μA | 500 | μA | 1 | High |
| | 1 | 100 μA | 0 | 0 | 500 | μA | 600 | μA | 0 | Low |

FIG. 5 is a circuit schematic diagram of a spin logic device according to an embodiment of the present disclosure. In this embodiment, by switching the circuit modes, the spin logic device can be implemented as a logic XOR gate, which is a key component for implementing a half adder and a full adder. As shown in FIG. 5, a spin logic device 300 comprises a current wiring 310 and a magnetic tunnel junction 320 arranged above it. Ports w, w′ for inputting currents can be set on both sides of the current wiring 310 to form a logic circuit with external current sources and other devices. The structures and materials of the current wiring 310 and the magnetic tunnel junction can be the same as those shown in FIGS. 1-2, which will not be repeated here.

The spin logic device 300 may further comprise a current source connected to the current wiring and a current-direction switching element for controlling the direction of the current flowing into the current wiring 310. The current source (shown in FIG. 5 at its high and low levels) is used to provide an input current to the current wiring 310 and the direction of the input current can be perpendicular to or at a non-zero angle to the magnetization axis of the free magnetic layer of the magnetic tunnel junction. When the current value reaches the set value, it can stimulate the free magnetic layer to flip the magnetization direction. In some embodiments, the current source can have multiple input sources similar to the current source shown in FIGS. 1-2, which can improve the functional scalability of the device. Alternatively, the current source can use a single current source, thereby simplifying the control method of the device.

The current-direction switching element can achieve the switching of the input direction of the input current under the control signal. For example, in one circuit mode, the input current flows from the w side to the w′ side, and in another circuit mode, the input current can flow from the w′ side to the w side. As shown in FIG. 5, the current-direction switching element comprises two pairs of gating switches (such as CMOS transmission gates), each pair of which is connected to both sides of the current wiring, and the control signals of the two pairs of gating switches are inverted.

Referring to FIG. 5, switching between the circuits A/B in FIG. 3 can be achieved through four transmission gates TG. TG1 and TG4 form a pair of switches to control the operation of the spin logic device in one circuit mode, and TG2 and TG3 form another pair of switches to control the operation of the spin logic device in another circuit mode. The control signals A and A of the two pairs of switches are in reverse phase. For example, when the control signal A in the transmission gate circuits TG1, TG2, TG3, and TG4 is 1 (high level), TG1 and TG4 are on (the resistance of the transmission gate itself in the on state is about 100 ohms), while TG2 and TG3 are off (impedance 10⁹ ohms). At this time, the current can flow along the solid line shown in the figure, which is equivalent to the circuit B in FIG. 3. If the control level A in TG1-TG4 is 0 (low level), TG1 and TG4 are off, TG2 and TG3 are on, and the current can flow along the dashed line shown in the figure, which is equivalent to the circuit A in FIG. 3.

As described earlier, in the circuit A and circuit B, the flipping characteristics of the magnetic tunnel junction SOT-MTJ are opposite. Based on this characteristic, the control signal A of the transmission gate and the input current I of the current source are configured as the logical input of the spin logic device 300. The control signal A of the transmission gate controls the current flow direction of the SOT-MTJ write channel; that is, it controls the flipping direction of the resistance-current dependence curve of the magnetic tunnel junction. The input current I of the current source controls the flipping of the magnetic tunnel junction between the high resistance state and the low resistance state, which can be implemented as a logical XOR gate by setting the magnitude of the input current and the control signal.

Refer to FIG. 5 and FIGS. 4A and 4B to illustrate the operating principle of the spin logic device 300. In an embodiment, that +600 μA flowing through the electrode between the positive pole High and the negative pole Low of the current source is defined as logic input 1, while −600 μA is defined as the logical input 0. When the control signal A is at a low level (corresponding to a logic input of 0), the spin logic device operates in the A-circuit mode with an input current I of −600 μA (i.e. corresponding to a logic input of 0), the magnetic tunnel junction remains in the low resistance state, i.e. the logic output remains in the 0 state, while the Input current I is +600 μA (i.e., the corresponding logic input is 1), the magnetic tunnel junction can be flipped to a high resistance state, and the corresponding logic output is 1. When the first logic input changes, such as when the control signal A is at a high level (corresponding to the logic input 1), the spin logic device operates in the B-circuit mode; when the input current is −600 μA (i.e., the corresponding logic input is 0), the magnetic tunnel junction is maintained in a high resistance state, i.e., the logic output is 1, while the input current I is +600 μA (i.e. the corresponding logic input is 1), the magnetic tunnel junction can be flipped to a low resistance state, and the corresponding logic output is 0. It can be seen that regardless of whether the spin logic device operates in the A-circuit mode or the B-circuit mode, whenever the input current I changes, the magnetic tunnel junction will undergo a resistive state flip, so there is no need to perform a reset operation.

As mentioned above, the spin logic device 300 implements logical XOR operations in accordance with the truth table shown in Table 6.

TABLE 6
Truth table of logical XOR gate

| Control level A of | | |
|---|---|---|
| transmission gate | Input current | Output current |

| Logic | Logic | | Logic | Resistance |
|---|---|---|---|---|
| input | input | Current | output | state |
| 0 | 0 | −600 μA | 0 | Low |
| 0 | 1 | −600 μA | 1 | High |
| 1 | 0 | −600 μA | 1 | High |
| 1 | 1 | −600 μA | 0 | Low |

In one embodiment, by adjusting the circuit shown in FIG. 5, the spin logic device can also be implemented as an XNOR gate. For example, the spin logic device can be implemented as XNOR gate by inverting the positive and negative poles of the current source, that is, connecting the positive pole to TG3 and TG4, and the negative pole to TG1 and TG2, while the definitions of other logic inputs and outputs remain unchanged, and its corresponding logic operations will not be repeated herein.

In the spin logic device of the present disclosure, logic operations can be achieved without an external magnetic field, resulting in a simpler structure and reduced device complexity. Moreover, the spin logic device of the present disclosure can be operated as various different logic gates, comprising XOR gates, resulting in that it achieves mode switching of the spin logic device by adjusting the current magnitude and direction, achieving a wide variety of spin logic devices. Therefore, it can be used as a programmable logic gate hardware, achieving a flexible configuration of circuit hardware.

Other embodiments of the present disclosure further provide an adder that comprises one or more combinations of the spin logic devices described earlier. For example, the XOR gate can be used as a 1-bit half adder, and the aforementioned 1-bit half adder can be combined with one AND gate to form a full adder. By expanding the number of 1-bit full adders mentioned above, it can be expanded to N-bit full adders.

Other embodiments of the present disclosure further provide an electronic apparatus, which can be, for example, but not limited to, a mobile phone, a laptop, a desktop computer, a tablet computer, a media player, a personal digital assistant, and a wearable electronic apparatus. Such electronic apparatus generally comprise, for example, controllers, processors, memories, etc., all of which contain logic circuits, and these logic circuits can be implemented using spin logic devices or adders of any of the previously described embodiments.

It can be understood that in the embodiments disclosed in this disclosure, the method of switching the circuits A and B to achieve different logic functions is also applicable to devices such as spin transfer torque (STT-MTJ), resistive storage units, and phase change storage units that have R-I hysteresis curves similar to SOT-MTJ devices, all of which are within the protection scope of this application.

In this disclosure, words such as “comprise”, “include”, “have”, etc. are open-ended terms that refer to “comprising but not limited to” and can be used interchangeably with them. The terms “or” and “and” used here refer to the words “and/or” and can be used interchangeably with them, unless the context clearly indicates otherwise. The phrase ‘such as’ used here refers to the phrase “such as but not limited to” and can be used interchangeably with it.

The above description of the disclosed aspects is provided to enable any person skilled in the art to make or use this application. The various modifications to these aspects are very obvious to those skilled in the art, and the general principles defined here can be applied to other aspects without departing from the scope of this application. For ordinary technical personnel in this field, it can be understood that certain modifications, substitutions, and changes can be made to the embodiments described above without departing from the principles and spirit of the present disclosure. Therefore, the present disclosure is not intended to be limited to the aspects shown here, but rather to the widest range consistent with the principles and novel features disclosed herein.

What is claimed is:

1. A spin logic device based on a magnetic tunnel junction, comprising:
a current wiring;
a magnetic tunnel junction, comprising: a free magnetic layer, a fixed magnetic layer, and a potential barrier layer located therebetween, three of which are all stacked on the current wiring; and
a current source for providing an input current to the current wiring, wherein the input current comprises a first in-plane current, a second in-plane current, and a third in-plane current, wherein directions of the first in-plane current, the second in-plane current, and the third in-plane current are all perpendicular to a direction of a magnetization axis of the free magnetic layer, or there is a vertical component in that direction, and at least one of the first in-plane current and the second in-plane current is configured as a logical input of the spin logic device, and the third in-plane current is used to control the implementation mode of the spin logic device.

2. The spin logic device of claim 1, wherein the spin logic device further comprises a current-direction control element for controlling an input direction of the input current.

3. The spin logic device of claim 2, wherein the current-direction control element comprises a gating switch.

4. The spin logic device of claim 1, wherein the spin logic device is configured to be implemented as a logic AND gate, a logic OR gate, a logic NOT gate, a logic NAND gate, or a logic NOR gate by setting magnitudes and directions of the first, second and third in-plane currents.

5. The spin logic device of claim 2, wherein the spin logic device is configured to be implemented as a logic AND gate, a logic OR gate, a logic NOT gate, a logic NAND gate, or a logic NOR gate by setting magnitudes and directions of the first, second and third in-plane currents.

6. The spin logic device of claim 1, wherein all of the first, second, and third in-plane currents three are pulse currents.

7. The spin logic device of claim 2, wherein all of the first, second, and third in-plane currents three are pulse currents.

8. The spin logic device of claim 1, further comprising:
a current-direction switching element for switching the input direction of the input current under a control signal, wherein the input current and the control signal is configured as logical inputs to the spin logic device.

9. The spin logic device of claim 8, wherein the current-direction switching element comprises two pairs of gating switches, each pair of which is respectively connected to both sides of the current wiring, and the control signals of the two pairs of gating switches are inverted.

10. The spin logic device of claim 9, wherein the spin logic device is configured to be implemented as a logic XOR gate or a logic XNOR gate by setting a magnitude of the input current and the control signal.

11. An adder, comprising a spin logic device based on a magnetic tunnel junction, comprising:
a current wiring;
a magnetic tunnel junction, comprising: a free magnetic layer, a fixed magnetic layer, and a potential barrier layer located therebetween, three of which are all stacked on the current wiring; and
a current source for providing an input current to the current wiring, wherein the input current comprises a first in-plane current, a second in-plane current, and a third in-plane current, wherein directions of the first in-plane current, the second in-plane current, and the third in-plane current are all perpendicular to a direction of a magnetization axis of the free magnetic layer, or there is a vertical component in that direction, and at least one of the first in-plane current and the second in-plane current is configured as a logical input of the spin logic device, and the third in-plane current is used to control the implementation mode of the spin logic device.

12. The adder of claim 11, wherein the spin logic device further comprises a current-direction control element for controlling an input direction of the input current.

13. The adder of claim 12, wherein the current-direction control element comprises a gating switch.

14. The adder of claim 11, wherein the spin logic device is configured to be implemented as a logic AND gate, a logic OR gate, a logic NOT gate, a logic NAND gate, or a logic NOR gate by setting magnitudes and directions of the first, second and third in-plane currents.

15. The adder of claim 12, wherein the spin logic device is configured to be implemented as a logic AND gate, a logic OR gate, a logic NOT gate, a logic NAND gate, or a logic NOR gate by setting magnitudes and directions of the first, second and third in-plane currents.

16. The adder of claim 11, wherein all of the first, second, and third in-plane currents three are pulse currents.

17. The adder of claim 12, wherein all of the first, second, and third in-plane currents three are pulse currents.

18. The adder of claim 11, wherein the spin logic device further comprises:
a current-direction switching element for switching the input direction of the input current under a control signal, wherein the input current and the control signal is configured as logical inputs to the spin logic device.

19. The adder of claim 18, wherein the current-direction switching element comprises two pairs of gating switches, each pair of which is respectively connected to both sides of the current wiring, and the control signals of the two pairs of gating switches are inverted.

20. An electronic apparatus, comprising an adder of claim 11.
